(19) United States
(12) Patent Application Publication
(10) Pub. No.: US 2010/0275090 A1
(43) Pub. Date: Oct. 28, 2010

(54) RADIO COMMUNICATION APPARATUS AND PUNCTURING METHOD

(75) Inventors: Kenichi Kuri, Kanagawa (JP); Akihiko Nishio, Kanagawa (JP); Katsuhiko Hiramatsu, Kanagawa (JP); Masaru Fukuoka, Ishikawa (JP); Hao Jiang, Beijing (CN)

Correspondence Address: Dickinson Wright PLLC;James E. Ledbetter, Esq., International Square, 1875 Eye Street, N.W., Suite 1200, Washington, DC, 20006, US

(73) Assignee: Panasonic Corporation, Osaka (JP)

(21) Appl. No.: 12/747,492

(22) PCT Filed: Dec. 14, 2007
(86) PCT No.: PCT/CN07/03601

§ 371 Date: Jun. 10, 2010

(51) Int. Cl. H03M 13/13; G06F 11/10

(52) U.S. Cl. 714/752; 714/E11.032; 714/790

(57) ABSTRACT

A radio communication apparatus is provided that enables degradation of error rate performance due to puncturing to be minimized when an LDPC code is used as an error correcting code. In this apparatus, a padding bit insertion section 101 inserts padding bits in a transmission bit sequence based on a parity check matrix, and outputs the generated bit sequence to an LDPC encoding section 102. Using the parity check matrix, LDPC encoding section 102 performs LDPC encoding on the bit sequence input from padding bit insertion section 101, and obtains an LDPC codeword composed of systematic bits and parity bits. Then a puncturing section 103 eliminates padding bits from the LDPC codeword input from. LDPC encoding section 102, and also punctures parity bits in the LDPC codeword in order starting from a parity bit corresponding to a variable node for which the total number of connections to padding bits via check nodes is larger.

### TECHNICAL FIELD

The present invention relates to a radio communication apparatus and puncturing method.

### BACKGROUND ART

In recent years, multimedia communication such as data communication and video streaming has continued to increase in popularity. Therefore, data sizes are expected to increase even more in the future, and growing demands for higher data rates for mobile communication services are also anticipated.

Thus, a fourth-generation mobile communication system called IMT-Advanced has been studied by the ITU-R (International Telecommunication Union Radio Communication Sector), and an LDPC (Low-Density Parity-Check) code is one of the error correcting codes for implementing a downlink speed of up to 1 Gbps. Use of an LDPC code as an error correcting code enables decoding processing to be parallelized, allowing decoding processing to be speeded up compared with the use of a turbo code that requires repeated serial execution of decoding processing.

LDPC encoding is performed using a parity check matrix containing a large number of 0s and a small number of 1s. A transmitting-side radio communication apparatus encodes a transmission bit sequence using a generation matrix or a parity check matrix having an LDGM (Low-Density Generation Matrix) structure, and obtains an LDPC codeword comprising systematic bits and parity bits. A receiving-side radio communication apparatus decodes received data by iteratively executing passing of the likelihood of individual bits in the parity check matrix row direction and the parity check matrix column direction, and obtains a received bit sequence. Here, the number of 1s contained in each column in a parity check matrix is called the column degree, and the number of 1s contained in each row in a parity check matrix is called the row degree. A parity check matrix can be represented by a Tanner graph, which is a two-part graph comprising rows and columns. In a Tanner graph, each row of a parity check matrix is called a check node, and each column of a parity check matrix is called a variable node. Variable nodes and check nodes of a Tanner graph are connected in accordance with the arrangement of 1s in the parity check matrix, and a receiving-side radio communication apparatus decodes received data by iteratively executing passing of likelihoods between connected, nodes, and obtains a received bit sequence.

There is a technology whereby, when the number of bits of a transmission bit sequence is smaller than the number of systematic bits in an LDPC codeword, encoding is performed with padding bits, which are known to both the transmitting-side radio communication apparatus and receiving-side radio communication apparatus, inserted in the transmission bit sequence, and the padding bits are eliminated from an obtained codeword.

A method of setting a coding rate higher than the LDPC code coding rate (hereinafter referred to as “mother coding rate”) is “puncturing.” Puncturing is a technology whereby specific bits of a codeword are thinned out. This enables a coding rate higher than the mother coding rate to be set.

Puncturing parity bits from a parity bit in ascending order of the column degree has been investigated as a conventional puncturing technology for LDPC codewords (see Patent Document 1).

### Patent Document 1: Unexamined Japanese Patent Publication No. 2006-54575

### DISCLOSURE OF INVENTION

### Problems to be Solved by the Invention

As padding bits are known to both the transmitting-side radio communication apparatus and receiving-side radio communication apparatus, the likelihood of padding bit is larger than the likelihood of other bits, being the maximum likelihood. Therefore, the effect on decoding performance—that is, error rate performance—due to a variable node corresponding to a padding bit passing a likelihood to another variable node is larger than the effect on error rate performance due to a variable node corresponding to another bit passing a likelihood to another variable node. Thus, error rate performance may degrade when puncturing is performed concentrating only on the column degree, as with the above-described conventional technology.

It is an object of the present invention to provide a radio communication apparatus and puncturing method that enable degradation of error rate performance due to puncturing to be minimized when an LDPC code is used as an error correcting code.

### Means for Solving the Problems

A radio communication apparatus of the present invention employs a configuration that includes an insertion section that inserts a padding bit in a first bit sequence to generate a second bit sequence, an encoding section that performs LDPC encoding using a parity check matrix on the second bit sequence to obtain a codeword comprising a systematic bit and a parity bits, and a puncturing section that, in the codeword, punctures parity bits from a parity bit corresponding to a variable node in descending order of total number of connections to the padding bit via a check node.

### Advantageous Effect of the Invention

The present invention enables degradation of error rate performance due to puncturing to be minimized when an LDPC code is used as an error correcting code.

### BRIEF DESCRIPTION OF DRAWINGS

FIG. 1 is a block configuration diagram of a transmitting-side radio communication apparatus according to Embodiment 1 of the present invention;

FIG. 2 is a parity check matrix according to Embodiment 1 of the present invention;

FIG. 3 is a Tanner graph according to Embodiment 1 of the present invention;

FIG. 4 is a drawing showing puncturing processing according to Embodiment 1 of the present invention;

FIG. 5 is a block configuration diagram of a receiving-side radio communication apparatus according to Embodiment 1 of the present invention;

FIG. 6 is a drawing showing padding processing according to Embodiment 1 of the present invention;

FIG. 7 is a parity check matrix according to Embodiment 2 of the present invention;

FIG. 8 is a Tanner graph according to Embodiment 2 of the present invention;

FIG. 9 is a drawing showing combinations of variable nodes according to Embodiment 2 of the present invention; and

FIG. 10 is a drawing showing puncturing processing according to Embodiment 2 of the present invention.

### BEST MODE FOR CARRYING OUT THE INVENTION

Embodiments of the present invention will now be described in detail with reference to the accompanying drawings.

In the following description, among columns of a parity check matrix or variable nodes of a Tanner graph, a part corresponding to a systematic bit is referred to as a systematic bit position, and a part corresponding to a parity bit is referred to as a parity bit position.

### Embodiment 1

In this embodiment, in an LDPC codeword, parity bits are punctured from a parity bit corresponding to a variable node in descending order of total number of connections to padding bits via check nodes.

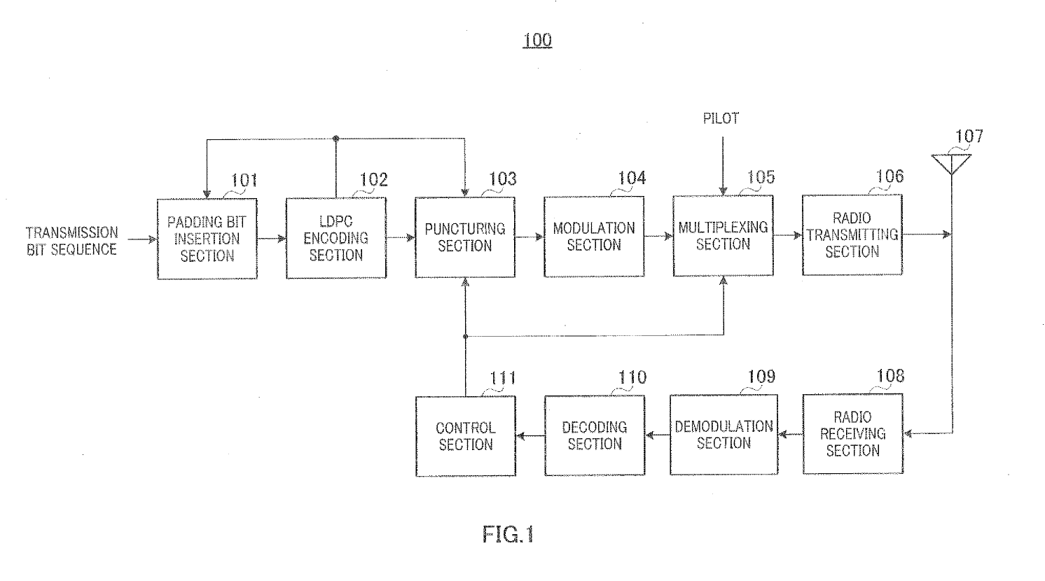

The configuration of a transmitting-side radio communication apparatus 100 according to this embodiment is shown in FIG. 1.

In transmitting-side radio communication apparatus 100, a transmission bit sequence is input to a padding bit insertion section 101. In addition, a parity check matrix is input to padding bit insertion section 101 from an LDPC encoding section 102. Padding bit insertion section 101 inserts padding bits in the transmission bit sequence based on the parity check matrix, and outputs the generated bit sequence to LDPC encoding section 102. The number of padding bits inserted is determined based on the difference between the number of systematic bits in an LDPC codeword and the number of bits in the transmission bit sequence. Specifically, the number of padding bits inserted is given by Nsys−Nd, where Nsys is the number of systematic bits in an LDPC codeword and Nd is the number of bits in the transmission bit sequence. Therefore, when Nd<Nsys, padding bit insertion section 101 inserts padding bits equivalent to the deficient number of bits, (Nsys−Nd), before outputting the transmission bit sequence to LDPC encoding section 102, whereas when Nd=Nsys, padding bit insertion section 101 outputs the transmission bit sequence as-is to LDPC encoding section 102.

Using the parity check matrix, LDPC encoding section 102 performs LDPC encoding on the bit sequence input from padding bit insertion section 101, to obtain an LDPC codeword comprising systematic bits and parity bits. This LDPC codeword is output to a puncturing section 103. LDPC encoding section 102 also outputs the parity check matrix to padding bit insertion section 101 and puncturing section 103.

Puncturing section 103 eliminates padding bits from the LDPC codeword input from LDPC encoding section 102, and also punctures parity bits of LDPC codeword in accordance with the parity check matrix input from LDPC encoding section 102. Then puncturing section 103 outputs the punctured LDPC codeword to a modulation section 104. The number of punctured parity bits is determined based on the difference between the LDPC codeword length and the transmit block size set by a control section 111. Details of puncturing processing by puncturing section 103 will be given later herein.

Modulation section 104 modulates the punctured LDPC codeword to generate data symbols, and outputs them to a multiplexing section 105.

Multiplexing section 105 multiplexes a data symbol, a pilot signal, and a control signal input from control section 111, and outputs a generated multiplex signal to a radio transmitting section 106.

Radio transmitting section 106 performs transmission processing such as D/A conversion, amplification, and up-conversion on the multiplex signal, and transmits the resulting signal to the receiving-side radio communication apparatus from an antenna 107.

Meanwhile, a radio receiving section 108 receives a control signal transmitted from the receiving-side radio communication apparatus via antenna 107, performs reception processing such as down-conversion and A/D conversion on the control signal, and outputs the resulting signal to a demodulation section 109. A CQI (Channel Quality Indicator) generated by the receiving-side radio communication apparatus is included in this control signal.

Demodulation section 109 demodulates the control signal and outputs the demodulated signal to a decoding section 110.

Decoding section 110 decodes the control signal and outputs the CQI contained in the control signal to control section 111.

Control section 111 controls LDPC codeword length after puncturing—that is, the transmit block size—according to the CQI, and also controls the coding rate of LDPC codeword after puncturing according to the CQI. Then control section 111 determines the transmit block size and coding rate according to the input CQI, and outputs the determined transmit block size and coding rate to puncturing section 103 and multiplexing section 105. The lower the channel quality to which the input CQI corresponds, the larger transmit block size and the lower the coding rate determined by control section 111.

Puncturing processing by puncturing section 103 will now be described in detail.

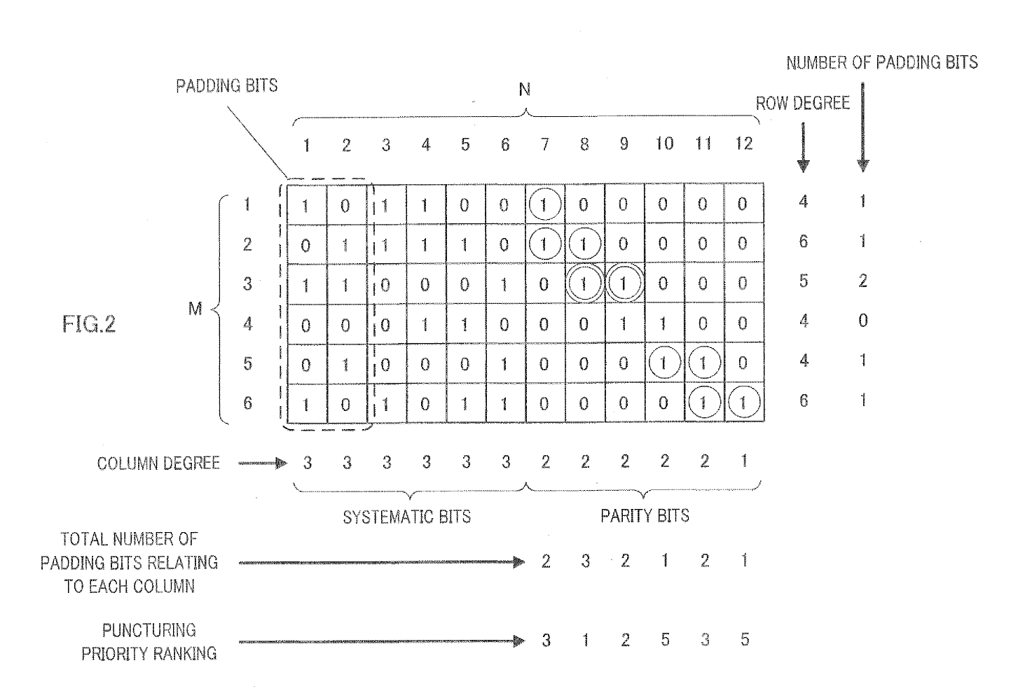

FIG. 2 shows a 6-row×12-column parity check matrix as an example. As shown here, a parity check matrix is represented by a matrix of M rows×N columns, and comprises 0s and 1s.

Each column of a parity check matrix corresponds to a bit of an LDPC codeword. That is to say, when LDPC encoding is performed using the parity check matrix shown in FIG. 2, a 12-bit LDPC codeword is obtained.

In the parity check matrix shown in FIG. 2, the column degree of the 1st column is the number of 1s in the 1st column—that is, three—and the column degree of the 2nd column is the number of 1s in the 2nd column—that is, three. The same kind of rationale also applies to the 3rd through 12th columns.

Thus, in the 12-bit LDPC codeword, the column degree of the 1st bit is three, and the column degree of the 2nd bit is three. The same kind of rationale also applies to the 3rd through 12th bits.

Similarly, in the parity check matrix shown in FIG. 2, the row degree of the 1st row is the number of 1s in the 1st row—that is, four—and the row degree of the 2nd row is the number of 1s in the 2nd row—that is, six. The same kind of rationale also applies to the 3rd through 6th rows.

The parity check matrix shown in FIG. 2 can be represented by a Tanner graph comprising the rows and columns of the parity check matrix.

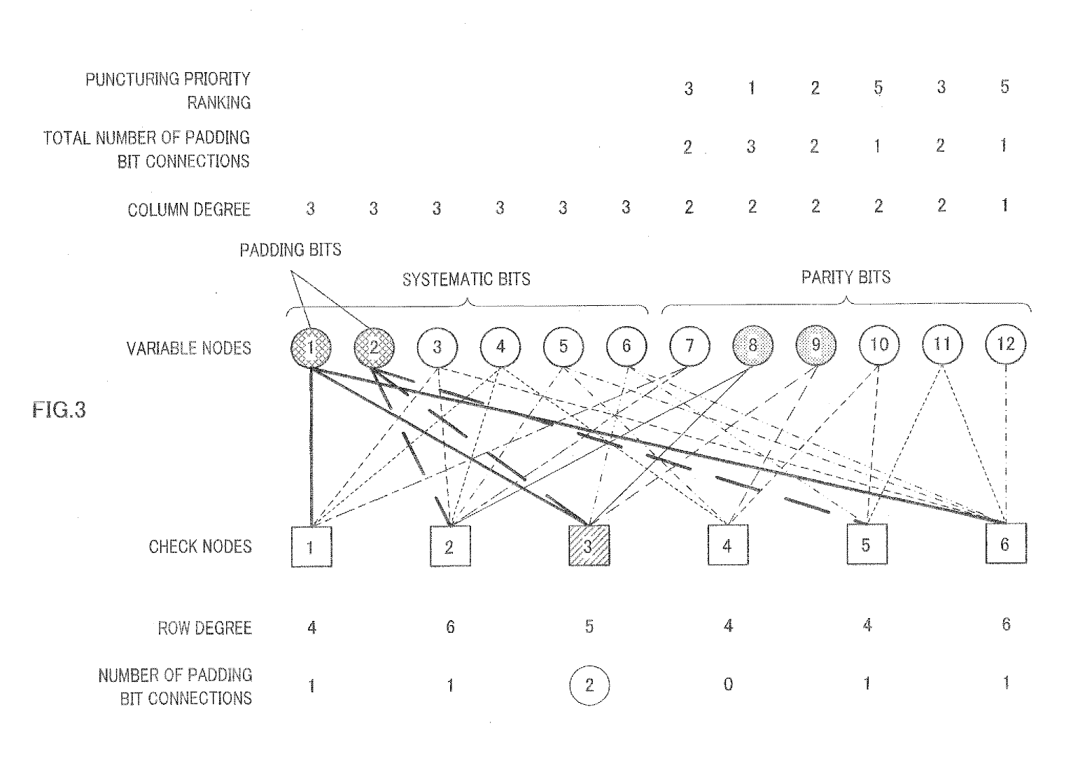

FIG. 3 shows a Tanner graph corresponding to the parity check matrix in FIG. 2. A Tanner graph comprises check nodes corresponding to the rows of a parity check matrix and variable nodes corresponding to the columns. That is to say, a Tanner graph corresponding to a 6-row×12-column parity check matrix is a two-part graph comprising six check nodes and twelve variable nodes.

Each variable node of a Tanner graph corresponds to a bit of the LDPC codeword.

Variable nodes and check nodes of a Tanner graph are connected in accordance with the arrangement of 1s in the parity check matrix.

A concrete description will be now given based on variable nodes. The 1st Variable node of the Tanner graph shown in. FIG. 3 corresponds to the 1st column (N=1) of the parity check matrix shown in FIG. 2. The column degree of the 1st column of the parity check matrix is three, and rows in which a 1 is located in the 1st column are the 1st row, 3rd row, and 6th row. Thus, there are three connections at the 1st variable node—1st check node, 3rd check node, and 6th check node. Similarly, the 2nd variable node of the Tanner graph corresponds to the 2nd column (N=2) of the parity check matrix, the column degree of the 2nd column of the parity check matrix is three, and rows in which a 1 is located in the 2nd column are the 2nd row, 3rd row, and 5th row. Thus, there are three connections at the 2nd variable node—2nd check node, 3rd check node, and 5th check node. The same kind of rationale also applies to the 3rd variable node through the 12th variable node.

Similarly, to give a concrete description based on check nodes, the 1st check node of the Tanner graph shown in FIG. 3 corresponds to the 1st row (M=1) of the parity check matrix shown in FIG. 2. The row degree of the 1st row of the parity check matrix is four, and columns in which a 1 is located in the 1st row are the 1st column, 3rd column, 4th column, and 7th column. Thus, there are four connections at the 1st check node—1st variable node, 3rd variable node, 4th variable node, and 7th variable node. Similarly, the 2nd check node of the Tanner graph corresponds to the 2nd row (M=2) of the parity cheek matrix, the row degree of the 2nd row of the parity check matrix is six, and columns in which a 1 is located in the 2nd row are the 2nd column, 3rd column, 4th column, 5th column, 7th column, and 8th column. Thus, there are six connections at the 2nd check node—2nd variable node, 3rd variable node, 4th variable node, 5th variable node, 7th variable node, and 8th variable node. The same kind of rationale also applies to 3rd check node through 6th check node.

Thus, in a Tanner graph, variable nodes and check nodes are connected in accordance with the arrangement of 1s in a parity check matrix. That is to say, the number of check nodes connected to each variable node in a Tanner graph is equal to the column degree of each column in a parity check matrix. Also, check nodes to which each variable node is connected in a Tanner graph are check nodes corresponding to rows in which a 1 is located in each column of a parity check matrix. Similarly, the number of variable nodes connected to each check node in a Tanner graph is equal to the row degree of each row in a parity check matrix, and variable nodes to which each check node is connected in a Tanner graph are variable nodes corresponding to columns in which a 1 is located in each row of a parity check matrix.

The receiving-side radio communication apparatus decodes received data by performing mutual passing of likelihoods between variable nodes via check nodes, and iteratively performing updating of the likelihood of each variable node. Also, the larger the likelihood of a variable node, the larger is the effect of likelihood updating of connected check nodes. Therefore, when parity bits are punctured, a check node with more connections to variable nodes corresponding to padding bits can pass a higher likelihood to variable nodes connected to that check node, with the result that degradation of an effect of likelihood updating due to puncturing is smaller.

Thus, puncturing section 103 punctures parity bits in an LDPC codeword from a parity bit corresponding to a variable node in descending order of total number of connections to the padding bit via a check node.

A description will be now given in concrete terms. In the following description, it is assumed that transmission bit sequence length Nd is 4 bits, LDPC codeword length N is 12 bits, mother coding rate Rm is ½, and the transmit block size determined by control section 111 is 8 bits. Also, padding bit insertion section 101 finds the number of padding bits inserted from Nsys−Nd, and two padding bits are inserted at the start of a transmission bit sequence. Here, Nsys is given by N*Rm. Therefore, when LDPC encoding is performed on a 6-bit sequence resulting from inserting two padding bits in a 4-bit transmission bit sequence using the parity check matrix shown in FIG. 2, an N=12-bit LDPC codeword comprising six systematic bits and six parity bits is obtained.

First, puncturing section 103 compares the number of connections to 1st variable node (the 1st column) and 2nd variable node (the 2nd column) corresponding to padding bits among 1st check node through 6th check node of the Tanner graph shown in FIG. 3 (the 1st row through 6th row in the parity check matrix shown in FIG. 2). That is to say, puncturing section 103 compares the number of connections (one connection) to padding bits at 1st check node (the number of columns (one) in which a 1 is located in the 1st column and 2nd column of the 1st row), the number of connections (one connection) to padding bits at 2nd check node (the number of columns (one) in which a 1 is located in the 1st column and 2nd column of the 2nd row), the number of connections (two connections) to padding bits at 3rd check node (the number of columns (two) in which a 1 is located in the 1st column and 2nd column of the 3rd row), the number of connections (zero) to padding bits at 4th check node (the number of columns (zero) in which a 1 is located in the 1st column and 2nd column of the 4th row), the number of connections (one connection) to padding bits at 5th check node (the number of columns (one) in which a 1 is located in the 1st column and 2nd column of the 5th row), and the number of connections (one connection) to padding bits at 6th check node (the number of columns (one) in which a 1 is located in the 1st column and 2nd column of the 6th row).

Next, puncturing section 103 compares the total number of connections to variable nodes corresponding to padding bits via check nodes among 7th variable node through 12th variable node corresponding to parity bits of the Tanner graph shown in FIG. 3 (the 7th column through 12th column in the parity check matrix shown in FIG. 2). That is to say, puncturing section 103 compares the total number of connections (two connections) to variable nodes corresponding to padding bits connected to 7th variable node via 1st check node and 2nd check node (the total number of 1s (two) located in the 1st column and 2nd column of the 1st row and 2nd row in which a 1 is located in the 7th column in FIG. 2), the total number of connections (three connections) to variable nodes corresponding to padding bits connected to 8th variable node via 2nd check node and 3rd check node (the total number of 1s (three) located in the 1st column and 2nd column of the 2nd row and 3rd row in which a 1 is located in the 8th column in FIG. 2), the total number of connections (two connections) to variable nodes corresponding to padding bits connected to 9th variable node via 3rd check node and 4th check node (the total number of 1s (two) located in the 1st column and 2nd column of the 3rd row and 4th row in which a 1 is located in the 9th column in FIG. 2), the total number of connections (one connection) to variable nodes corresponding to padding bits connected to 10th variable node via 4th check node and 5th check node (the total number of 1s (one) located in the 1st column and 2nd column of the 4th row and 5th row in which a 1 is located in the 10th column in FIG. 2), the total number of connections (two connections) to variable nodes corresponding to padding bits connected to 11th variable node via 5th check node and 6th check node (the total number of 1s (two) located in the 1st column and 2nd column of the 5th row and 6th row in which a 1 is located in the 11th column in FIG. 2), and the total number of connections (one connection) to variable nodes corresponding to padding bits connected to 12th variable node via 6th check node (the total number of 1s (one) located in the 1st column and 2nd column of the 6th row in which a 1 is located in the 12th column in FIG. 2).

Then parity bits as puncturing candidates are extracted from a parity bit corresponding to a variable node in descending order of number of total connections to variable nodes corresponding to padding bits. That is to say, from 7th variable node through 12th variable node of the Tanner graph shown in FIG. 3 (the 7th column through 12th column corresponding to parity bits of the parity check matrix shown in FIG. 2), puncturing section 103 extracts 8th variable node, which has the largest total number of connections to variable nodes corresponding to padding bits (namely, three connections), as a puncturing candidate.

Furthermore, since the number of parity bits to be punctured is two, puncturing section 103 extracts 7th variable node, 9th variable node, and 11th variable node, having the second-largest total number of connections to variable nodes corresponding to padding bits (namely, two connections), as puncturing candidates.

For puncturing section 103, the remaining number of parity bits to be punctured, apart from 8th variable node (the 8th column) having the largest total number of connections to variable nodes corresponding to padding bits, is one, but the number of parity bits corresponding to variable nodes having the same total number of connections to variable nodes corresponding to padding bits (namely, two connections)—that is, the number of extracted columns—is three, as shown in FIG. 3.

Thus, for this plurality of parity bits, puncturing section 103 further punctures parity bits from a parity bit corresponding to a variable node connected to a check node in descending order of the number of connections to variable nodes corresponding to padding bits.

That is to say, for 7th variable node, 9th variable node, and 11th variable node of the Tanner graph shown in FIG. 3, puncturing section 103 further compares the number of connections to padding bits for each check node connected to each thereof. Thus, puncturing section 103 compares the number of connections (one connection) to padding bits at 1st check node, and the number of connections (one connection) to padding bits at 2nd check node, to which 7th variable node is connected, the number of connections (two connections) to padding bits at 3rd check node, to which 9th variable node is connected, and the number of connections (one connection) to padding bits at 5th check node, and the number of connections (one connection) to padding bits at 6th check node, to which 11th variable node is connected. Then puncturing section 103 extracts parity bits deemed to be puncturing candidates from a variable node connected to a check node in descending order of number of connections to variable nodes corresponding to padding bits. That is to say, among 7th variable node, 9th variable node, and 11th variable node of the Tanner graph shown in FIG. 3 (the 7th column, 9th column, and 11th column of the parity check matrix shown in FIG. 2), puncturing section 103 gives the highest puncturing priority to 9th variable node connected to 3rd check node for which the number of connections to variable nodes corresponding to padding bits is two.

Therefore, as shown in FIG. 3, the puncturing priority rankings in 7th variable node through 12th variable node (the 7th column through 12th column) are as follows: 8th variable node (the 8th column) first, 9th variable node (the 9th column) second, 7th variable node (the 7th column) and 11th variable node (the 11th column) third, and 10th variable node (the 10th column) and 12th variable node (the 12th column) fifth.

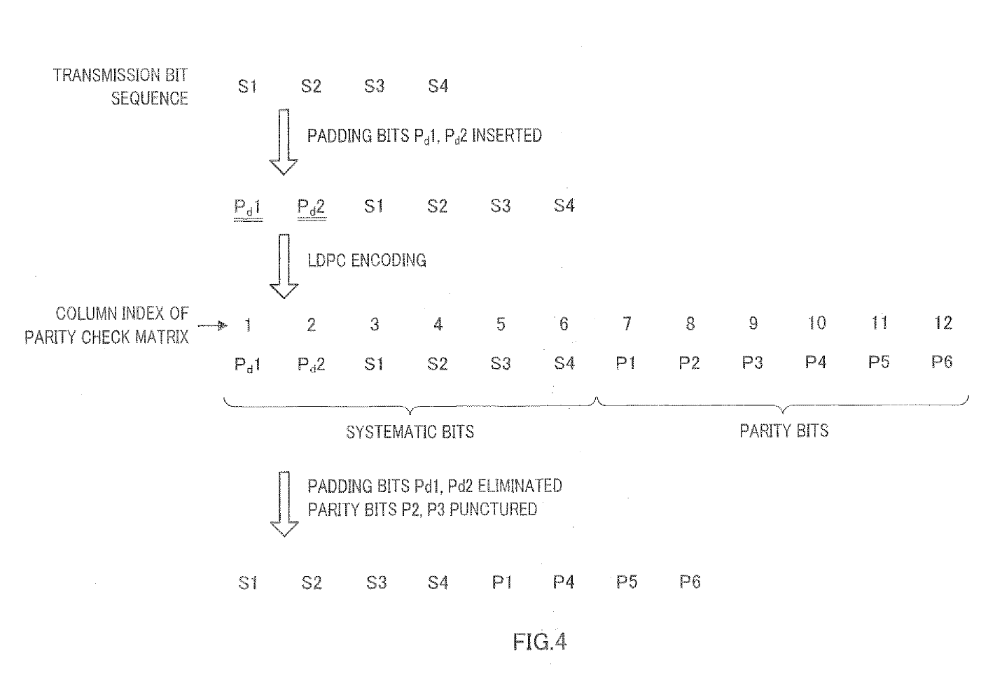

Then, since the number of parity bits to be punctured is two, in a 12-bit LDPC codeword comprising six systematic bits P_{d}1, P_{d}2, S1, S2, S3, and S4 resulting from the insertion of two padding bits in a 4-bit transmission bit sequence, and six parity bits P1 through P6, as shown in FIG. 4, puncturing section 103 punctures 8th column (8th variable node) parity bit P2 and 9th column (9th variable node) parity bit P3 in accordance with the puncturing priority rankings. Also, puncturing section 103 eliminates 1st column (1st variable node) padding bit P_{d}1 and 2nd column (2nd variable node) padding bit P_{d}2. By this means, puncturing section 103 can obtain an 8-bit LDPC codeword comprising four systematic bits S1 through S4, and four parity bits P1, P4, P5, and P6.

Thus, according to this embodiment, parity bits in an LDPC codeword are punctured from a parity bit corresponding to a variable node in descending order of total number of connections to padding bits via check nodes. Consequently, a high likelihood held by a padding bit that is known by both the transmitting-side radio communication apparatus and the receiving-side radio communication apparatus can be passed to a punctured variable node via a check node. Therefore, LDPC encoding can be performed in which degradation of error rate performance due to puncturing is minimized.

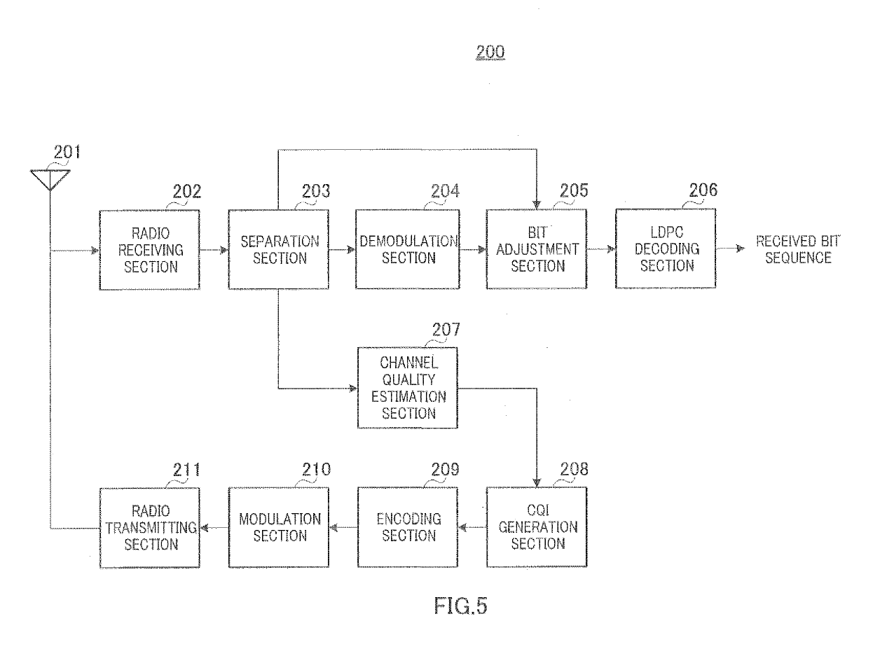

Next, a receiving-side radio communication apparatus according to this embodiment will be described. The configuration of a receiving-side radio communication apparatus 200 according to this embodiment is shown in FIG. 5.

In receiving-side radio communication apparatus 200, a radio receiving section 202 receives a multiplex signal transmitted from transmitting-side radio communication apparatus 100 (FIG. 1) via an antenna 201, performs reception processing such as down-conversion and A/D conversion on the received signal, and outputs the resulting signal to a separation section 203. This received signal includes a data symbol, a pilot signal, and a control signal indicating a transmit block size and coding rate determined by transmitting-side radio communication apparatus 100.

Separation section 203 separates the received signal into a data symbol, pilot signal, and control signal. Then separation section 203 outputs the data symbol to a demodulation section 204, outputs the pilot signal to a channel quality estimation section 207, and outputs the control signal to a bit adjustment section 205.

Demodulation section 204 demodulates the data symbol and obtains received data, and outputs the received data to bit adjustment section 205.

Bit adjustment section 205 pads the received data with padding bits known by both the transmitting-side radio communication apparatus and receiving-side radio communication apparatus at systematic bit positions inserted by padding bit insertion section 101 (FIG. 1), and also pads the received data with a logarithmic likelihood ratio 0 bit at a parity bit position punctured by puncturing section 103 (FIG. 1). Then bit adjustment section 205 outputs the obtained received data to an LDPC decoding section 206. The number of padding bits used for padding is determined based on the difference between the LDPC decoding section 206 coding rate—that is, coding rate (mother coding rate) Rm of LDPC encoding section 102 (FIG. 1)—and coding rate R (the coding rate determined by control section 111 (FIG. 1)) indicated by the control signal input from separation section 203. Specifically, the number of padding bits used for padding is given by N*Rm−Nr*R, where Nr indicates the received data length. That is to say, the number of padding bits used for padding is equal to the number of padding bits inserted in transmitting-side radio communication apparatus 100 (FIG. 1).

Also, the number of logarithmic likelihood ratio 0 bits used for padding is determined based on the difference between LDPC decoding section 206 coding rate Rm and coding rate R indicated by the control signal input from separation section 203. Specifically, the number of logarithmic likelihood ratio 0 bits used for padding is given by (1−Rm)N−(1−R)Nr. That is to say, the number of logarithmic likelihood ratio 0 bits used for padding is equal to the number of punctured parity bits in transmitting-side radio communication apparatus 100 (FIG. 1). Details of the bit adjustment processing performed by bit adjustment section 205 will be given later herein.

Using a parity check matrix identical to the parity check matrix used by LDPC encoding section 102 (FIG. 1), LDPC decoding section 206 performs LDPC decoding on data input from bit adjustment section 205, to obtain a received bit sequence.

Meanwhile, channel quality estimation section 207 estimates the channel quality using the pilot signal input from separation section 203. Here, channel quality estimation section 207 estimates the SINR (Signal to Interference and Noise Ratio) of the pilot signal as channel quality, and outputs the estimated SINR to a CQI generation section 208.

CQI generation section 208 generates a CQI corresponding to the input SINR, and outputs this to an encoding section 209.

Encoding section 209 encodes the CQI and outputs the encoded CQI to a modulation section 210.

Modulation section 210 modulates the CQI to generate a control signal, and outputs this control signal to a radio transmitting section 211.

Radio transmitting section 211 performs transmission processing such as D/A conversion, amplification, and up-conversion on the control signal, and transmits the resulting signal to transmitting-side radio communication apparatus 100 (FIG. 1) from antenna 201.

The bit adjustment processing performed by bit adjustment section 205 will now be described in detail.

In a similar way to puncturing section 103 of transmitting-side radio communication apparatus 100 (FIG. 1), bit adjustment section 205 pads received data with logarithmic likelihood ratio 0 bits at parity bit positions from a parity bit position corresponding to variable node in descending order of total number of connections to padding bits via check nodes.

Here, since received data length Nr is 8 bits and coding rate R is ½, bit adjustment section 205 finds the number of padding bits used for padding from N*Rm−Nr*R, and pads with two padding bits at the start of the received data. Also, bit adjustment section 205 finds the number of logarithmic likelihood ratio 0 bits used for padding from (1−Rm)N−(1−R)Nr,and pads with two logarithmic likelihood ratio 0 bits.

In the same way as puncturing section 103 (FIG. 1), from 7th variable node through 12th variable node of the Tanner graph shown in FIG. 3 (the 7th column through 12th column corresponding to parity bits of the parity check matrix shown in FIG. 2), bit adjustment section 205 extracts 8th variable node having the largest total number of connections to variable nodes corresponding to padding bits (namely, three connections), and 7th variable node, 9th variable node, and 11th variable node, having the second-largest total number of connections to variable nodes corresponding to padding bits (namely, two connections).

For bit adjustment section 205, the remaining number of logarithmic likelihood ratio 0 bits to be used for padding, apart from 8th variable node (the 8th column) having the largest total number of connections to variable nodes corresponding to padding bits, is one, but the number of variable nodes having the same total number of connections to variable nodes corresponding to padding bits (namely, two connections)—that is, the number of extracted columns—is three, as shown in FIG. 3.

Thus, for each variable node of this plurality of variable nodes, bit adjustment section 205 further extracts parity bit positions as padding candidates from a parity bit position corresponding to a variable node connected to a check node in descending order of number of connections to variable nodes corresponding to padding bits.

That is to say, in a similar way to puncturing section 103 (FIG. 1), for 7th variable node, 9th variable node, and 11th variable node of the Tanner graph shown in FIG. 3, bit adjustment section 205 further compares the number of connections to padding bits for each connected check node. Thus, bit adjustment section 205 compares the number of connections (one connection) to padding bits at 1st check node, and the number of connections (one connection) to padding bits at 2nd check node, to which 7th variable node is connected, the number of connections (two connections) to padding bits at 3rd check node, to which 9th variable node is connected, and the number of connections (one connection) to padding bits at 5th check node, and the number of connections (one connection) to padding bits at 6th check node, to which 11th variable node is connected. Then bit adjustment section 205 extracts parity bits as puncturing candidates from a variable node connected to a check node in descending order of number of connections to variable nodes corresponding to padding bits. That is to say, among 7th variable node, 9th variable node, and 11th variable node of the Tanner graph shown in FIG. 3 (the 7th column, 9th column, and 11th column of the parity check matrix shown in FIG. 2), bit adjustment section 205 gives the highest padding priority to 9th variable node connected to 3rd check node for which the number of connections to variable nodes corresponding to padding bits is two.

Therefore, as shown in FIG. 3, the puncturing priority rankings of parity bit positions to be padded with logarithmic likelihood ratio 0 bits at 7th variable node through 12th variable node (the 7th column through 12th column) are as follows: 8th variable node (the 8th column) first, 9th variable node (the 9th column) second, 7th variable node (the 7th column) and 11th variable node (the 11th column) third, and 10th variable node (the 10th column) and 12th variable node (the 12th column) fifth.

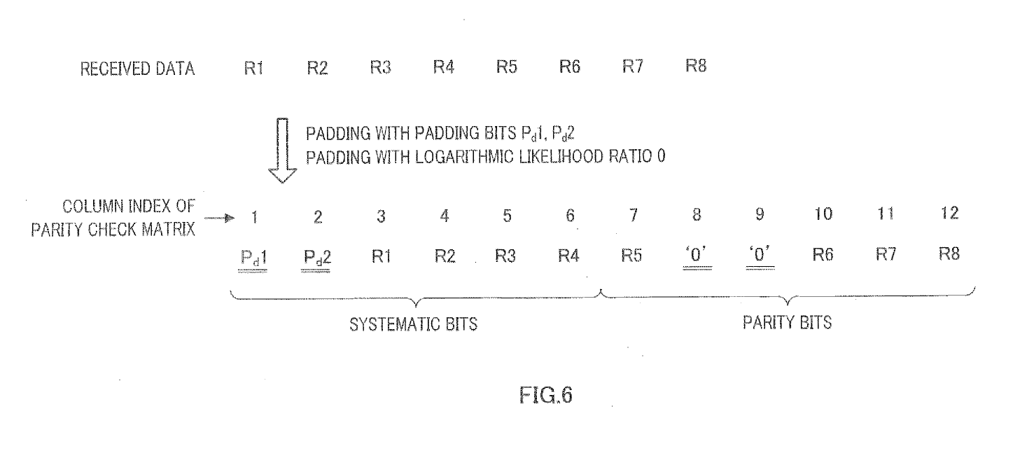

Then, as shown in FIG. 6, bit adjustment section 205 pads 8-bit received data comprising bits R1 through R8 with padding bits P_{d}1 and P_{d}2 at systematic bit positions corresponding to 1st variable node (the 1st column) and 2nd variable node (the 2nd column)—that is, before 1st bit R1 at the start of the received data. Also, since the number of logarithmic likelihood ratio 0 bits to be used for padding is two, as shown in FIG. 6, bit adjustment section 205 pads with two logarithmic likelihood ratio 0 bits at the parity bit positions corresponding to 8th variable node (the 8th column) and 9th variable node (the 9th column) respectively—that is, between R5 and R6. By this means, R6 through R8 are each shifted by two bits. Here, the parity bit positions at which padding with logarithmic likelihood ratio 0 bits is performed coincide with the positions of parity bits P2 and P3 punctured by transmitting-side radio communication apparatus 100 (FIG. 1).

In this way, bit adjustment section 205 identifies parity bit positions at which logarithmic likelihood ratio 0 bit padding is performed based on a parity check matrix identical to the parity check matrix used by puncturing section 103 of transmitting-side radio communication apparatus 100. By this means, 12-bit data (received data after padding) with the same data length as an LDPC codeword generated by transmitting-side radio communication apparatus 100 can be obtained without the parity bit positions at which puncturing is performed by transmitting-side radio communication apparatus 100 being reported by transmitting-side radio communication apparatus 100.

Thus, according to this embodiment, received data is padded with logarithmic likelihood ratio 0 bits at parity bit positions from a parity bit position corresponding to variable nodes in descending order of total number of connections to variable nodes corresponding to padding bits via check nodes. Therefore, more high likelihoods of padding bits are provided preferentially via check nodes to variable nodes for which logarithmic likelihood ratio 0 bit padding is performed, and LDPC encoding can be performed in which degradation of the effect of likelihood updating is minimized. Consequently, degradation of error rate performance due to puncturing can be minimized.

Furthermore, according to this embodiment, a receiving-side radio communication apparatus can identify parity bit positions at which logarithmic likelihood ratio 0 bit padding is performed without the parity bit positions at which puncturing is performed being reported by the transmitting-side radio communication apparatus, enabling LDPC decoding to be performed that enables optimal error rate performance to be obtained at all times without increasing overhead due to reported information.

### Embodiment 2

Whereas in Embodiment 1 a case has been described in which padding bits are inserted at positions set beforehand between the transmitting-side radio communication apparatus and receiving-side radio communication apparatus, in this embodiment a case will be described in which the positions at which padding bits are inserted are determined based on a parity check matrix.

The operation of a padding bit insertion section 101 according to this embodiment will now be described. A case is here described in which two padding bits are inserted in a transmission bit sequence, and one parity bit is punctured.

The receiving-side radio communication apparatus performs mutual likelihood passing between variable nodes via check nodes. Therefore, the larger the number of check node connections of a variable node (the larger the column degree of a variable node), the greater is the number of times likelihood passing is performed to other variable nodes.

Also, the more variable nodes having a higher likelihood that are connected to a check node, the higher the likelihoods that can be passed to other variable nodes connected via that check node, and the greater is the effect of likelihood updating.

Thus, padding bit insertion section 101 according to this embodiment inserts padding bits in a transmission bit sequence at a plurality of systematic bit positions corresponding to variable nodes belonging to a combination for which the total number of connections to check nodes of each variable node is larger, and the total number of connections to an identical check node of each variable node is larger, among a plurality of combinations of variable nodes.

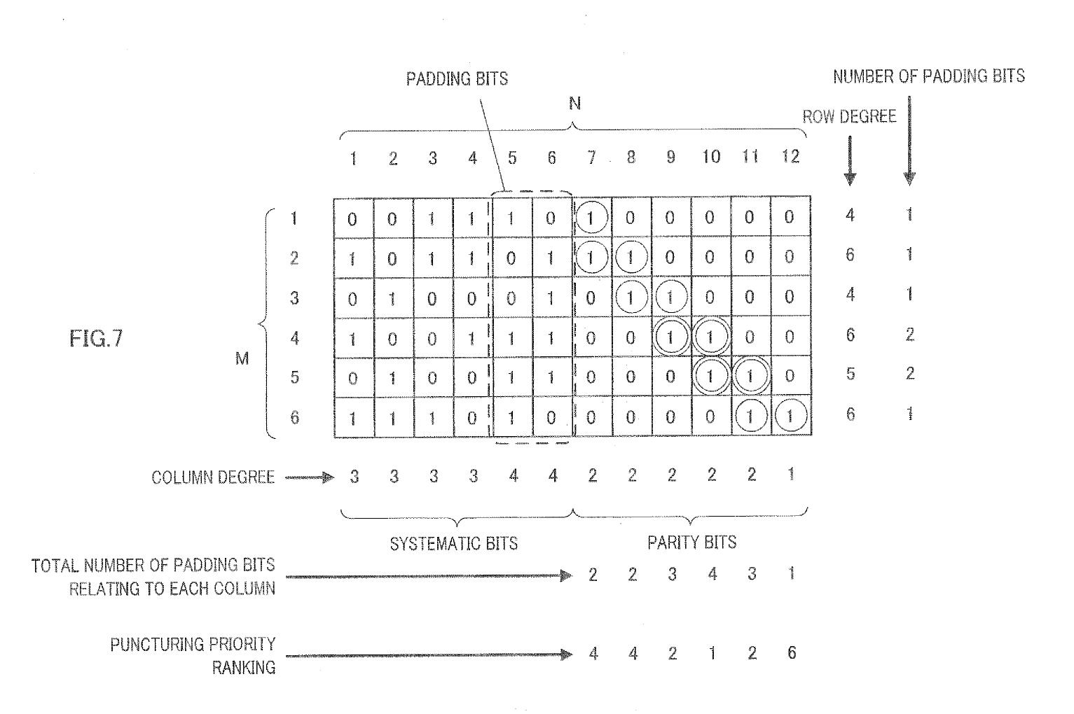

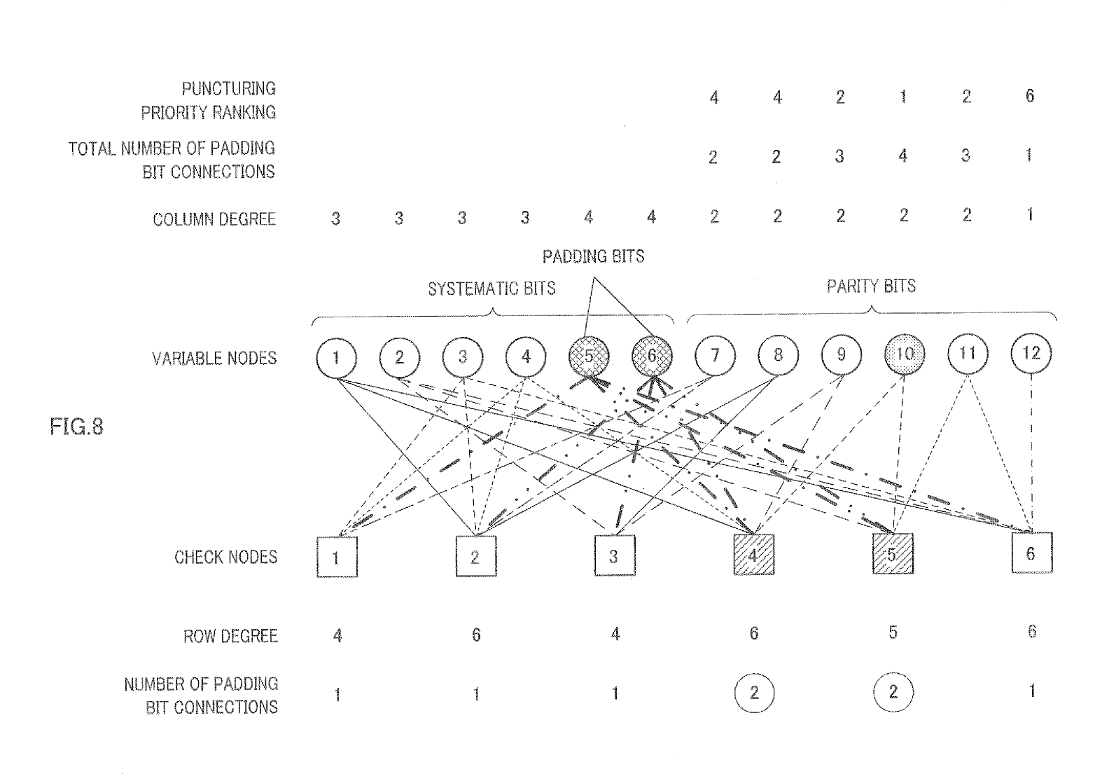

A concrete example will now be given of padding bit insertion processing by padding bit insertion section 101. In the following description, LDPC encoding is performed using the parity check matrix shown in FIG. 7 instead of the parity cheek matrix shown in FIG. 2. A Tanner graph corresponding to the parity check matrix shown in FIG. 7 is shown in FIG. 8.

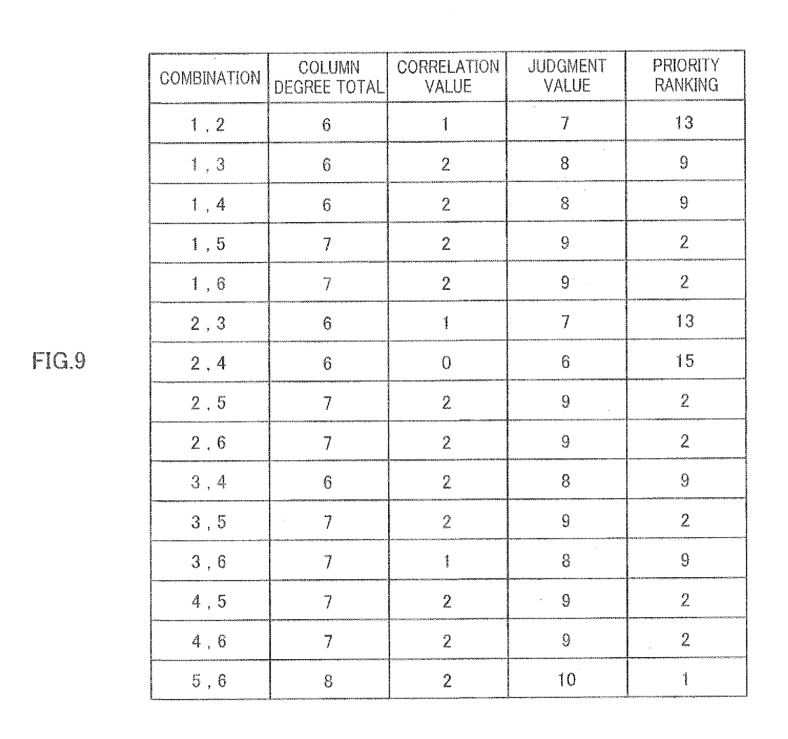

First, padding bit insertion section 101 calculates the total number of connections to check nodes of each variable node belonging to each combination among all combinations when two variable nodes are extracted from the six variable nodes (1st variable node through 6th variable node) corresponding to the systematic bits in the Tanner graph shown in FIG. 8. That is to say, padding bit insertion section 101 calculates the total of the column degrees of each variable node belonging to each combination. In the Tanner graph shown in FIG. 8, the column degree of 1st variable node is three, and the column degree of 2nd variable node is three, and therefore the total of the column degrees of combination (1, 2) comprising 1st variable node and 2nd variable node is six, as shown in FIG. 9. Also, in the Tanner graph shown in FIG. 8, the column degree of 3rd variable node is three, and therefore the total of the column degrees of combination (1, 3) comprising 1st variable node and 3rd variable node is six, as shown in FIG. 9. Similarly, the total of the column degrees of combination (1, 4) comprising 1st variable node and 4th variable node is six, the total of the column degrees of combination (1, 5) comprising 1st variable node and 5th variable node is seven, and the total of the column degrees of combination (1, 6) comprising 1st variable node and 6th variable node is seven. The same process also gives the column degree totals for combination (2, 3) through combination (5, 6) shown in FIG. 9.

Next, padding bit insertion section 101 finds the number duplicately connected to the same check node between variable nodes in each combination (hereinafter referred to as the correlation value). The correlation value is equal to the number of rows in which a 1 is located in the same row between variable nodes in the parity check matrix shown in FIG. 7. In the Tanner graph shown in FIG. 8, 1st variable node and 2nd variable node are duplicately connected to 6th check node, and therefore the correlation value of combination (1, 2) is one, as shown in FIG. 9. Also, in the Tanner graph shown in FIG. 8, 1st variable node and 3rd variable node are duplicately connected to two check nodes—2nd check node and 6th check node—and therefore the correlation value of combination (1, 3) is two, as shown in FIG. 9. Similarly, the correlation value of combination (1, 4) is two, the correlation value of combination (1, 5) is two, and the correlation value of combination (1, 6) is two. The same process also gives the correlation values for combination (2, 3) through combination (5, 6) shown in FIG. 9.

Furthermore, padding bit insertion section 101 finds the total. of the column degree total and correlation value for each combination (hereinafter referred to as the judgment value). Here, a combination for which a number of connections to check nodes is larger and a number of connections to an identical check node is larger, has a larger judgment value. As shown in FIG. 9, combination (1, 2) has a column degree total of six and a correlation value of one, and therefore has a judgment value of seven. Also, as shown in FIG. 9, combination (1, 3) has a column degree total of six and a correlation value of two, and therefore has a judgment value of eight. The same process also gives the judgment values for combination (1, 4) through combination (5, 6) shown in FIG. 9.

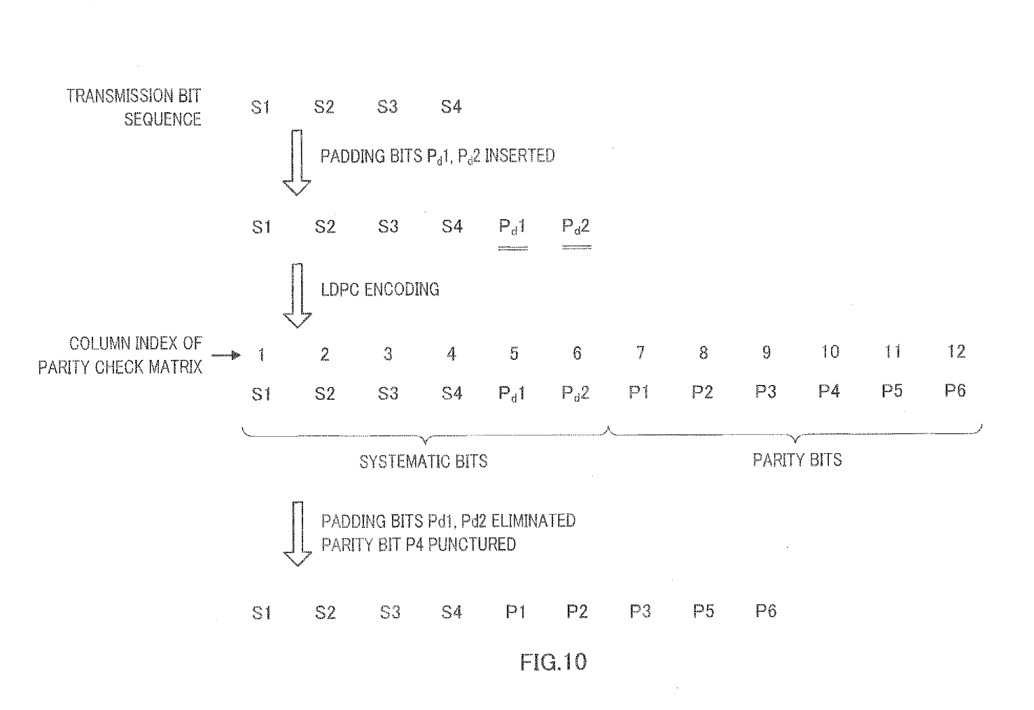

Then padding bit insertion section 101 selects a combination with the largest judgment value, and inserts padding bits in the transmission bit sequence at a plurality of systematic bit positions corresponding to each variable node belonging to that combination. Thus, as shown in FIG. 10, in the 4-bit transmission bit sequence S1, S2, S3, S4, padding bit insertion section 101 inserts padding bits P_{d}1 and P_{d}2 at systematic bit positions corresponding to 5th variable node and 6th variable node belonging to combination (5, 6) having the largest judgment value shown in FIG. 9, namely ten—that is, after 4th bit S4 of the transmission bit sequence. By this means, padding bit insertion section 101 can obtain a 6-bit sequence S1, S2, S3, S4, P_{d}1, P_{d}2, on which LDPC encoding is performed. Then LDPC encoding is performed on the 6-bit sequence S1, S2, S3, S4,P_{d}1, P_{d}2 by LDPC encoding section 102, and a 12-bit LDPC codeword comprising six systematic bits S1, S2, S3, S4, P_{d}1, P_{d}2 and six parity bits P1 through P6 is obtained.

Also, using the same method as in Embodiment 1, puncturing section 103 identifies parity bit positions to be punctured and the number of parity bits to be punctured. Specifically, puncturing section 103 compares the total number of connections to variable nodes corresponding to padding bits connected via check nodes among 7th variable node through 12th variable node corresponding to parity bits of the Tanner graph shown in FIG. 8 (the 7th column through 12th column in the parity check matrix shown in FIG. 7). Therefore, as shown in FIG. 8, the puncturing priority rankings in 7th variable node through 12th variable node (the 7th column through 12th column) are as follows: 10th variable node (the 10th column) first with a total of four connections to padding bits, 9th variable node (the 9th column) and 11th variable node (the 11th column) second with a total of three connections each to padding bits, 7th variable node (the 7th column) and 8th variable node (the 8th column) fourth with a total of two connections each to padding bits, and 12th variable node (the 12th column) sixth with a total of one connection to a padding bit.

Then, since the number of parity bits to be punctured is one, in a 12-bit LDPC codeword comprising six systematic hits S1, S2, S3, S4, P_{d}1, P_{d}2 and six parity bits P1 through P6, as shown in FIG. 10, puncturing section 103 punctures 10th column (10th variable node) parity bit P4 in accordance with the puncturing priority ranking. Thus, as shown in FIG. 10, by means of puncturing section 103, padding bits P_{d}1 and P_{d}2 are eliminated from the 12-bit LDPC codeword and parity bit P4 is punctured, and a 9-bit LDPC codeword is obtained.

Also, bit adjustment section 205 of receiving-side radio communication apparatus 200 (FIG. 5) identifies systematic bit positions at which padding is performed with padding bits using the same method as padding bit insertion section 101, and identifies parity bit positions at which puncturing is performed using the same method as puncturing section 103.

Thus, according to this embodiment, padding bits are inserted in a transmission bit sequence at systematic bit positions corresponding to each variable nodes belonging to a combination for which the total number of connections to check nodes is larger and the total number of connections to an identical check node is larger. By this means, high likelihoods of padding bits can be passed to many check nodes, enabling the effect of likelihood updating at each variable node to be improved. Furthermore, high likelihoods of a plurality of padding bits connected via an identical check node can be passed preferentially to a punctured parity bit position, enabling degradation of error rate performance due to puncturing to be minimized.

The combination selection method according to this embodiment is only an example, and a different combination selection method may also be used as long as it enables the selection of a combination for which the number of connections to check nodes is larger and the number of connections to an identical check node is larger from among a plurality of combinations of variable nodes.

This completes the description of embodiments of the present invention.

In the above embodiments, the number of punctured parity bits is determined based on the difference between the LDPC codeword length and the transmit block size set by control section 111. However, the number of punctured parity bits may also be determined based on the difference between the mother coding rate and coding rate R of an LDDC codeword after puncturing set by control section 111. For example, the number of punctured parity bits can be found from N(1−(Rm/R))−Npad(1−(1/R)), where Npad denotes the number of padding bits used for padding.

A padding bit used in the above embodiments may be either a 1 or a 0, as long as this is known (common) to both the transmitting-side radio communication apparatus and receiving-side radio communication apparatus. For example, a padding bit sequence may be a sequence of all 0s, a sequence of all 1s, or a common sequence comprising 0s and 1s.

In the above embodiments, a case in which the present invention is implemented in an FDD (Frequency Division Duplex) system has been taken as an example, but it is also possible for the present invention to be implemented in a TDD (Time Division Duplex) system. In the case of a TDD system, correlativity between uplink propagation path characteristics and downlink propagation path characteristics is extremely high, and therefore transmitting-side radio communication apparatus 100 can estimate reception quality in receiving-side radio communication apparatus 200 using a signal from receiving-side radio communication apparatus 200. Therefore, in the case of a TDD system, channel quality may be estimated by transmitting-side radio communication apparatus 100 without having receiving-side radio communication apparatus 200 issue a channel quality notification by means of a CQI.

The parity check matrixes shown in FIG. 2 and FIG. 7 are only examples, and parity check matrixes that can be used in implementing the present invention are not limited to those shown in FIG. 2 and FIG. 7.

The transmit block size and coding rate set by control section 111 of transmitting-side radio communication apparatus 100 are not limited to those determined according to channel quality, and may also be fixed.

In the above embodiments, SINR is estimated as channel quality, but SNR, SIR, CINR, received power, interference power, bit error rate, throughput, an MCS (Modulation and Coding Scheme) that enables a predetermined error rate to be achieved, or the like, may be estimated as channel quality instead. Furthermore, CQI may also be expressed as CSI (Channel State Information).

In a mobile communication system, transmitting-side radio communication apparatus 100 can be provided in a radio communication base station apparatus, and receiving-side radio communication apparatus 200 can be provided in a radio communication mobile station apparatus. Also, transmitting-side radio communication apparatus 100 can be provided in a radio communication mobile station apparatus, and receiving-side radio communication apparatus 200 can be provided in a radio communication base station apparatus. By this means, a radio communication base station apparatus and radio communication mobile station apparatus can be implemented that offer the same kind of operation and effects as described above.

A radio communication mobile station apparatus may be referred to as “UE”, and a radio communication base station apparatus as “Node B”.

In the above embodiments, a case has been described by way of example in which the present invention is configured as hardware, but it is also possible for the present invention to be implemented by software.

The function blocks used in the descriptions of the above embodiments are typically implemented as LSIs, which are integrated circuits. These may be implemented individually as single chips, or a single chip may incorporate some or all of them. Here, the term LSI has been used, but the terms IC, system LSI, super LSI, and ultra LSI may also be used according to differences in the degree of integration.

The method of implementing integrated circuitry is not limited to LSI, and implementation by means of dedicated circuitry or a general-purpose processor may also be used. An FPGA (Field Programmable Gate Array) for which programming is possible after LSI fabrication, or a reconfigurable processor allowing reconfiguration of circuit cell connections and settings within an LSI, may also be used.

In the event of the introduction of an integrated circuit implementation technology whereby LSI is replaced by a different technology as an advance in, or derivation from, semiconductor technology, integration of the function blocks may of course be performed using that technology. The adaptation of biotechnology or the like is also a possibility.

### INDUSTRIAL APPLICABILITY

The present invention can be applied to a mobile communication system or the like.

1. A transmitting-side radio communication apparatus comprising:
an insertion section that inserts a padding bit in a first bit sequence to generate a second bit sequence;
an encoding section that performs LDPC encoding using a parity check matrix on the second bit sequence to obtain a codeword comprising a systematic bit and a parity bit; and
a puncturing section that, in the codeword, punctures parity bits from a parity bit corresponding to a variable node in descending order of total number of connections to the padding bit via a check node.

2. The radio communication apparatus according to claim 1, wherein the insertion section inserts a number of padding bits determined based on a difference between a number of the systematic bits and a number of bits of the first bit sequence.

3. The radio communication apparatus according to claim 1, wherein the puncturing section, when there are a plurality of parity bits for which a total of the number of connections is identical, punctures, for each parity bit of that plurality of parity bits, parity bits from a parity bit corresponding to a variable node connected to a check node in descending order of the number of connections.

4. The radio communication apparatus according to claim 1, wherein the insertion section inserts, in the first bit sequence, the padding bit at a plurality of systematic bit positions corresponding to each variable node belonging to a combination for which a total of a number of connections to a check node of each variable node is larger, and a total of a number of connections to an identical check node of each variable node is larger, among a plurality of combinations of variable nodes.

5. A receiving-side radio communication apparatus comprising:
a padding section that pads a received bit sequence with a padding bit to generate first received data, and also pads the first received data with a logarithmic likelihood ratio 0 bit at parity bit positions from a parity bit position corresponding to a variable node in descending order of total number of connections to the padding bit via a check node, to generate second received data; and
a decoding section that performs LDPC decoding on the second received data using a parity check matrix to obtain a decoded bit sequence.

6. The radio communication apparatus according to claim 1, wherein the radio communication apparatus comprises one of a radio communication base station apparatus and a radio communication mobile station apparatus.

7. The radio communication apparatus according to claim 5, wherein the radio communication apparatus comprises one of a radio communication base station apparatus and a radio communication mobile station apparatus.

8. A puncturing method for a codeword comprising a systematic bit and a parity bit obtained by performing LDPC encoding using a parity check matrix on a bit sequence containing a transmission bit sequence and a padding bit,
wherein, for each parity bit of the codeword, parity bits are punctured from a parity bit corresponding to a variable node in descending order of total number of connections to the padding bit via a check node.
